(19) United States
(12) Patent Application Publication
(10) Pub. No.: US 2008/0283922 A1
(43) Pub. Date: Nov. 20, 2008

(54) SEMICONDUCTOR DEVICE AND MANUFACTURING METHOD THEREOF

(76) Inventors: Kyoji YAMASHITA, Kyoto (JP); Daisaku IKOMA, Kyoto (JP)

Correspondence Address: MCDERMOTT WILL & EMERY LLP, 600 13TH STREET, NW, WASHINGTON, DC, 20005-3096, US

(21) Appl. No.: 12/020,758

(22) Filed: Jan. 28, 2008

(30) Foreign Application Priority Data
May 17, 2007 (JP) 2007-131497

(51) Int. Cl. H01L 29/00; H01L 21/336

(52) U.S. Cl. 257/365; 438/279; 257/E21.409; 257/E29.001

(57) ABSTRACT

A semiconductor device includes a first conductivity type well formed on a semiconductor substrate, and a first transistor and a second transistor formed on the well. The first transistor has first pocket regions containing a first conductivity type impurity and first source/drain regions containing a second conductivity type impurity, and the second transistor has second pocket regions containing a first conductivity type impurity and second source/drain regions containing a second conductivity type impurity, and executes an analog function. A concentration of the first conductivity type impurity contained in the source-side and the drain-side second pocket regions is lower than a concentration of the first conductivity type impurity included in the first pocket regions.

### BACKGROUND OF THE INVENTION

1. Field of the Invention

The present invention relates to a semiconductor device and a manufacturing method thereof. More particularly, the present invention relates to a semiconductor device structure having a less variation in characteristics and an implanting method for producing the same.

2. Description of the Related Art

As the miniaturization advances, the cell area of an SRAM (Static Random Access Memory) is reduced in accordance with scaling. A power supply voltage applied to an SRAM cell is currently as low as about 1.2 V. A sense amplifier, for which a considerably small variation in characteristics is required, includes a 1.2-V transistor as in the SRAM cell, but the gate length of the transistor is not minimum, and is relatively large, specifically about four times as large as the minimum gate length. Therefore, the sense amplifier, which requires a large drive force, is also designed to have a large gate width. To reduce the size of a whole LSI chip, however, it is desirable for a transistor included in the sense amplifier to have as small a gate length and gate width as possible.

On the other hand, in the 130- to 45-nm generations, core transistors have a power supply voltage of 1.2 V, and I/O transistors and analog transistors have a power supply voltage of 1.8 V, 2.5 V, 3.3 V or the like. As the miniaturization advances, the proportion of an analog transistor in the chip area increases. In view of low power consumption, the use of 1.2-V transistors is desirable.

In 1.2-V transistors, so-called pocket implantation, in which an impurity of a conductivity type opposite to that of an extension region is implanted below the extension region, is generally performed so as to suppress the influence of a short-channel effect. Therefore, there is a considerably large variation in characteristics of the 1.2-V transistor. Japanese Unexamined Patent Application Publication No. 2003-509863 discloses a technique for reducing a variation in characteristics. Hereinafter, the technique will be described in detail.

FIG. 7 is a cross-sectional view showing a conventional semiconductor device. Here, an N-channel MOS transistor will be described as an example.

In FIG. 7, Tr1 indicates a 1.2-V core transistor and Tr2 indicates a 1.2-V analog transistor. The conventional semiconductor device comprises a P-type well 103 provided in a P-type semiconductor substrate 101, an isolation region 104 formed in the semiconductor substrate 101 (P-type well 103), active regions 103a and 103b of the semiconductor substrate 101 surrounded by the isolation region 104, and the transistors Tr1 and Tr2 formed on the active regions 103a and 103b, respectively.

Tr1 has a gate insulating film 106a and a gate electrode 107a which are provided on the active region 103a in this order from below, a sidewall 110a, and source/drain regions 111a, source/drain extension portions (extension regions) 108a, and pocket regions 109a which are provided in the active region 103a. Tr2 has a gate insulating film 106b and a gate electrode 107b which are provided on the active region 103b in this order from below, a sidewall 110b, and source/drain regions 111b and source and drain extension portions 108b which are provided in the active region 103b. The gate insulating film 106a has the same thickness as the gate insulating film 106b.

In the conventional semiconductor device of FIG. 7, while the pocket region 109a is provided in the 1.2-V core transistor Tr1, a pocket region is not provided in the 1.2-V analog transistor Tr2. Thereby, a variation in characteristics of Tr2 is significantly reduced as compared to when pocket implantation is performed.

Next, a method for manufacturing the conventional semiconductor device will be described with reference to FIGS. 8A to 8C. FIGS. 8A to 8C are cross-sectional views showing the manufacturing method of the conventional semiconductor device.

Firstly, as shown in FIG. 8(a), the P-type well 103, the active regions 103a and 103b, the isolation region 104, and the gate insulating films 106a and 106b are formed in or on the semiconductor substrate 101. Thereafter, a polysilicon film is deposited on an entire surface of the semiconductor substrate 101, followed by selective dry etching to form the gate electrodes 107a and 107b. Next, an n-type impurity is implanted into regions of the active region 103a located at opposite sides of the gate electrode 107a, and regions of the active region 103b located at opposite sides of the gate electrode 107b, to form the source/drain region extension portions 108a and 108b, respectively.

Next, as shown in FIG. 8(b), by implanting a p-type impurity into the active region 103a while covering the active region 103b using a resist mask 201, the pocket regions 109a of the 1.2-V core transistor Tr1 are formed. Conventionally, due to the resist mask 201, a pocket region is not formed in the 1.2-V analog transistor Tr2.

Next, as shown in FIG. 8(c), after the resist mask 201 is removed, an insulating film is deposited on a whole surface of the semiconductor substrate 101, and thereafter, the insulating film is subjected to dry etching to self-selectively form the sidewalls 110a and 110b on side surfaces of the gate electrodes 107a and 107b, respectively. Thereafter, by implanting an n-type impurity into the active regions 103a and 103b, the source/drain regions 111a and 111b are formed, respectively.

### SUMMARY OF THE INVENTION

However, in the technique of Japanese Unexamined Patent Application Publication No. 2003-509863, a mask for preventing a pocket region from being formed in the active region of an analog transistor is additionally formed, resulting in an increase in manufacturing cost. If a pocket region is not formed in a core transistor, a gate length needs to be larger than necessary due to a short-channel effect.

In view of the above-described problems, an object of the present invention is to provide a semiconductor device in which a variation in characteristics of a transistor is reduced and which can be manufactured without increasing the number of masks.

A semiconductor device according to the present invention comprises a first transistor and a second transistor. The first transistor includes a first active region surrounded by an isolation region formed in a semiconductor substrate, a first gate insulating film formed on the first active region, a first gate electrode formed on the first gate insulating film, and first pocket regions of a first conductivity type formed at opposite sides of the first gate electrode in the first active region. The second transistor includes a second active region surrounded by an isolation region formed in the semiconductor substrate, a second gate insulating film formed on the second active region, a second gate electrode formed on the second gate insulating film, and second pocket regions of the first conductivity type formed at opposite sides of the second gate electrode in the second active region. A concentration of an impurity of the first conductivity type in the second pocket regions is lower than a concentration of an impurity of the first conductivity type in the first pocket regions.

Thereby, in the second transistor, the ratio of the amount of the first conductivity type impurity in the second pocket region to the amount of a first conductivity type impurity introduced for adjustment of the threshold voltage can be reduced, so that a variation in electrical characteristics of the second transistor can be suppressed while suppressing a short-channel effect in the first transistor. This is particularly effective when the first transistor and the second transistor have the same power supply voltage and when the second transistor has a gate length longer than that of the first transistor.

In a method for manufacturing the semiconductor device of the present invention, at least a source-side pocket region of the second pocket regions in the second transistor is formed at the same time when pocket regions of a third transistor are formed. Thereby, the semiconductor device in which a variation in electrical characteristics of the second transistor can be suppressed while suppressing a short-channel effect in the first transistor, can be manufactured by a smaller number of steps.

### BRIEF DESCRIPTION OF THE DRAWINGS

FIG. 1 is a diagram showing a relationship between a threshold voltage Vth and a gate length L of MOS transistors including pocket regions, where the dose of an impurity implanted for adjustment of the threshold voltage is varied.

FIG. 2 is a diagram showing a relationship between random variations (σVth) in Vth and 1/√L in MOS transistors having different doses of the threshold voltage adjusting impurity.

FIG. 3 is a cross-sectional view showing a semiconductor device according to a first embodiment of the present invention.

FIGS. 4A to 4C are cross-sectional views showing steps of manufacturing the semiconductor device of the first embodiment.

FIG. 5 is a cross-sectional view showing a semiconductor device according to a second embodiment of the present invention.

FIGS. 6A to 6C are cross-sectional views showing steps of manufacturing the semiconductor device of the second embodiment.

FIG. 7 is a cross-sectional view showing a conventional semiconductor device.

FIGS. 8A to 8C are cross-sectional views showing a method for manufacturing the conventional semiconductor device.

### DETAILED DESCRIPTION OF THE PREFERRED EMBODIMENTS

Factors which cause a random variation in a transistor will be described prior to description of embodiments of the present invention.

In 1989, Pelgrom proposed a general law of a random variation in transistor characteristics. Specifically, σVth is inversely proportional to √(LW), where σVth indicates a random variation in threshold voltage of a transistor, L indicates a gate length, and W indicates a gate width. Here, Pelgrom's coefficient P is defined by:

P=σVth*√(LW) (1)

As can be seen from this expression, Pelgrom's coefficient P is constant, independently from the gate length L and the gate width W.

However, Pelgrom's general law is not satisfied in the design rule of the 130- to 45-nm generations. Details will be described, showing actual data.

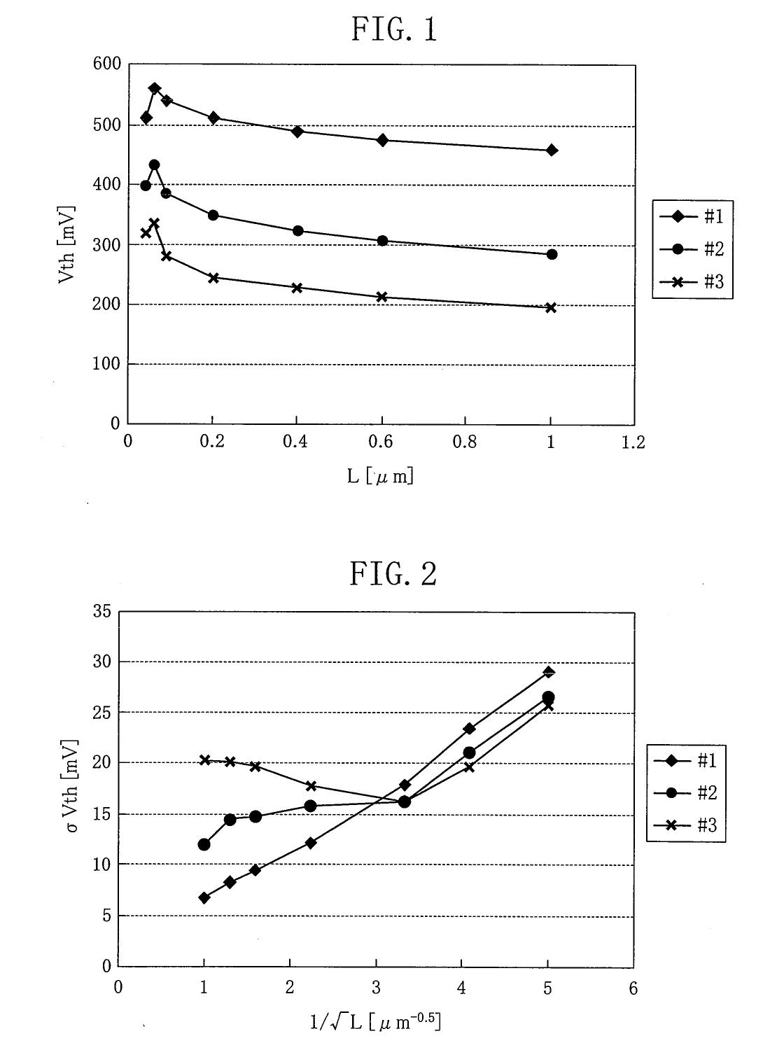

FIG. 1 is a diagram showing a relationship between the threshold voltage Vth and the gate length L of MOS transistors including pocket regions, where the dose of an impurity implanted for adjustment of the threshold voltage is varied. Here, the threshold voltage adjusting impurity is introduced into a P-type well immediately below the gate electrode. The impurity doses are #1>#2>#3.

As can be seen from FIG. 1, in the transistors having pocket regions, as the gate length L is decreased from 1 μm to 0.06 μm, the threshold voltage Vth increases (so-called reverse short-channel characteristics). Also, in these transistors, if the gate length L is between 0.06 μm and 0.04 μm, typical short-channel characteristics are exhibited.

The reverse short-channel effect is a phenomenon which is caused by the following reason: even when the gate length L is decreased, the dose of pocket implantation is constant, and the effective channel concentration increases with a decrease in the gate length L. A measure for the reverse short channel is defined by:

ΔVth=(maximum of Vth)−(Vth of long-channel transistor) (2)

Here, the “long-channel transistor” is assumed to be a transistor in which the dose of the threshold voltage adjusting impurity is equal to that of the transistor of interest and the gate length L is 1 μm. It is considered that the influence of pocket implantation increases with an increase in ΔVth.

FIG. 2 is a diagram showing a relationship between random variations (σVth) in Vth and 1/√L in MOS transistors having different doses of the threshold voltage adjusting impurity. Note that, in FIG. 2, the gate width W is constantly 0.42 μm. These transistors #1, #2, and #3 are the same as those of FIG. 1. The diagram of FIG. 2 is a so-called Pelgrom's plot, in which σVth is ideally proportional to 1/√L as described above. However, as can be seen from FIG. 2, whereas σVth is substantially proportional to 1/√L in the transistor #1, σVth does not decrease where L is 0.09 μm or more, i.e., 1/√L is 3.3 or less, in the transistors #2 and #3. Conversely, in the transistor #3, σVth increases where 1/√L is 3.3 or less. As can be seen from FIG. 1, in the transistor #3, the dose of the threshold voltage adjusting impurity is small, so that Vth is low and ΔVth is large. This is because the proportion of the dose of pocket implantation in Vth is large, resulting in a large influence of pocket implantation.

As described above, it has been experimentally clarified that if the ratio of the dose of pocket implantation to the dose of the threshold voltage adjusting impurity is large, then when the gate length L is large, random variations in transistor are not reduced. Embodiments of the present invention will be hereinafter described based on the experimental results above.

### First Embodiment

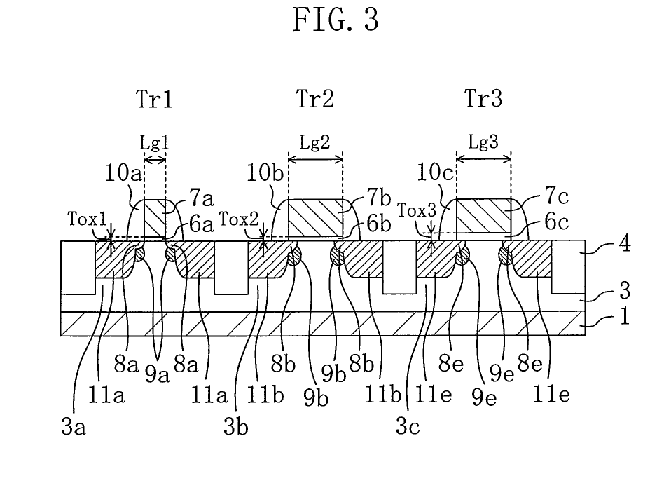

FIG. 3 is a cross-sectional view showing a semiconductor device according to a first embodiment of the present invention. In this embodiment, an N-channel MOS transistor will be described as an example, though the present invention is also applicable to a P-channel MOS transistor. In FIG. 3, Tr1 indicates a 1.2-V core transistor, Tr2 indicates a 1.2-V analog transistor, and Tr3 indicates a 1.8-V transistor. Although Tr3 is assumed to be a 1.8-V transistor in this embodiment, a 2.5- or 3.3-V transistor can also be applicable to the semiconductor device of the present invention. Note that an “analog transistor” refers to a transistor which executes an analog function in a circuit. Although most analog transistors have a longer gate length than that of core transistors, an analog transistor may have basically the same structure as that of a core transistor.

As shown in FIG. 3, the semiconductor device of this embodiment comprises a P-type well 3 provided in a P-type semiconductor substrate 1, an isolation region 4 formed in the semiconductor substrate 1 (the P-type well 3), active regions 3a, 3b, and 3c made of the semiconductor substrate 1 surrounded by the isolation region 4, and the transistors Tr1, Tr2, and Tr3 formed on the active regions 3a, 3b, and 3c, respectively.

The transistor Tr1 has a gate insulating film 6a and a gate electrode 7a provided on the active region 3a in this order from below, a sidewall 10a provided on a side surface of the gate electrode 7a, extension regions 8a provided in regions of the active region 3a located below the sidewall 10a and including an n-type impurity, source/drain regions 3a provided in regions of the active region 3a located at opposite sides of the gate electrode 7a and the sidewall 10a and including an n-type impurity having a higher concentration than that of the extension regions 8a, and pocket regions 9a provided below the extension regions 8a and including a p-type impurity. The pocket regions 9a are provided below opposite end portions of the gate electrode 7a, contacting both the source/drain regions 11a and the extension regions 8a.

The transistor Tr2 has a gate insulating film 6b and a gate electrode 7b provided on the active region 3b in this order from below, a sidewall 10b provided on a side surface of the gate electrode 7b, extension regions 8b provided in regions of the active region 3b located below the sidewall 10b and including an n-type impurity, source/drain regions 11b provided in regions of the active region 3b located at opposite sides of the gate electrode 7b and the sidewall 10b and including an n-type impurity having a higher concentration than that of the extension regions 8b, and pocket regions 9b provided below the extension regions 8b and including a p-type impurity. The pocket regions 9b are provided below opposite end portions of the gate electrode 7b, contacting both the source/drain regions 11b and the extension regions 8b.

The transistor Tr3 has a gate insulating film 6c and a gate electrode 7c provided on the active region 3c in this order from below, a sidewall 10c provided on a side surface of the gate electrode 7c, extension regions 8e provided in regions of the active region 3c located below the sidewall 10c and including an n-type impurity, source/drain regions 11e provided in regions of the active region 3c located at opposite sides of the gate electrode 7c and the sidewall 10c and including an n-type impurity having a higher concentration than that of the extension regions 8e, and pocket regions 9e provided below the extension regions 8e and including a p-type impurity. The impurity concentrations of regions immediately below the gate electrodes of the active regions 3a, 3b, and 3c are set to be 3a=3b>3c. In FIG. 3, the gate length (denoted Lg1) of the transistor Tr1, the gate length (denoted Lg2) of the transistor Tr2, and the gate length (denoted by Lg3) of the transistor Tr3 satisfy:

(minimum of Lg1)<(minimum of Lg2)<(minimum of Lg3) (3)

Lg1<Lg2<Lg3 is satisfied in most cases as well as when each gate length takes the minimum value possible in design.

The film thickness (denoted Tox1) of the gate insulating film 6a of the transistor Tr1, the film thickness (denoted Tox2) of the gate insulating film 6b of the transistor Tr2, and the film thickness (denoted Tox3) of the gate insulating film 6c of the transistor Tr3 satisfy:

Tox1=Tox2<Tox3 (4)

The impurity concentration (denoted N8a) of the extension region 8a, the impurity concentration (denoted N8b) of the extension region 8b, the impurity concentration (denoted N8e) of the extension region 8e, the impurity concentration (denoted N9a) of the pocket region 9a, the impurity concentration (denoted N9b) of the pocket region 9b, and the impurity concentration (denoted N9e) of the pocket region 9e satisfy:

N8a>N8b=N8e (5)

N9a>N9b=N9e (6)

Specific numerical values are exemplified as follows, assuming the 45-nm generation process: the minimum value of Lg1=0.04 μm, the minimum value of Lg2=0.10 μm, the minimum value of Lg3=0.18 μm, Tox1=Tox2=2 nm, and Tox3=3.5 nm.

The semiconductor device of this embodiment is characterized in that, in the core transistor and the analog transistor having the same power supply voltage, the extension region and the pocket region may have different impurity concentrations. Also, the n-type impurity concentration of the extension region 8b of the 1.2-V analog transistor Tr2 is equal to the n-type impurity concentration of the extension region 8e of the transistor Tr3 having a larger power supply voltage, and the p-type impurity concentration of the pocket region 9b of the analog transistor Tr2 is equal to the p-type impurity concentration of the pocket region 9e of the transistor Tr3.

Therefore, the impurity concentration of the pocket region 9b of the 1.2-V analog transistor Tr2 can be set to be lower than the impurity concentration of the pocket region 9a of the 1.2-V core transistor Tr1, so that the ratio of the dose of the p-type impurity for pocket implantation to the dose of the p-type impurity for adjusting the threshold voltage can be reduced, thereby making it possible to reduce the influence of pocket implantation. Therefore, a random variation in characteristics of the analog transistor can be reduced while suppressing the influence of a short-channel effect of the transistor Tr1. Note that the impurity concentration of the extension region 8b of the 1.2-V analog transistor Tr2 is lower than the impurity concentration of the extension region 8a of the 1.2-V core transistor Tr1. Despite this, the minimum value of the gate length Lg2 of the 1.2-V analog transistor Tr2 is 0.10 μm, which is larger than the minimum value 0.04 μm of Lg1, so that the influence of a decrease in impurity concentration of the extension region 8b is not very large.

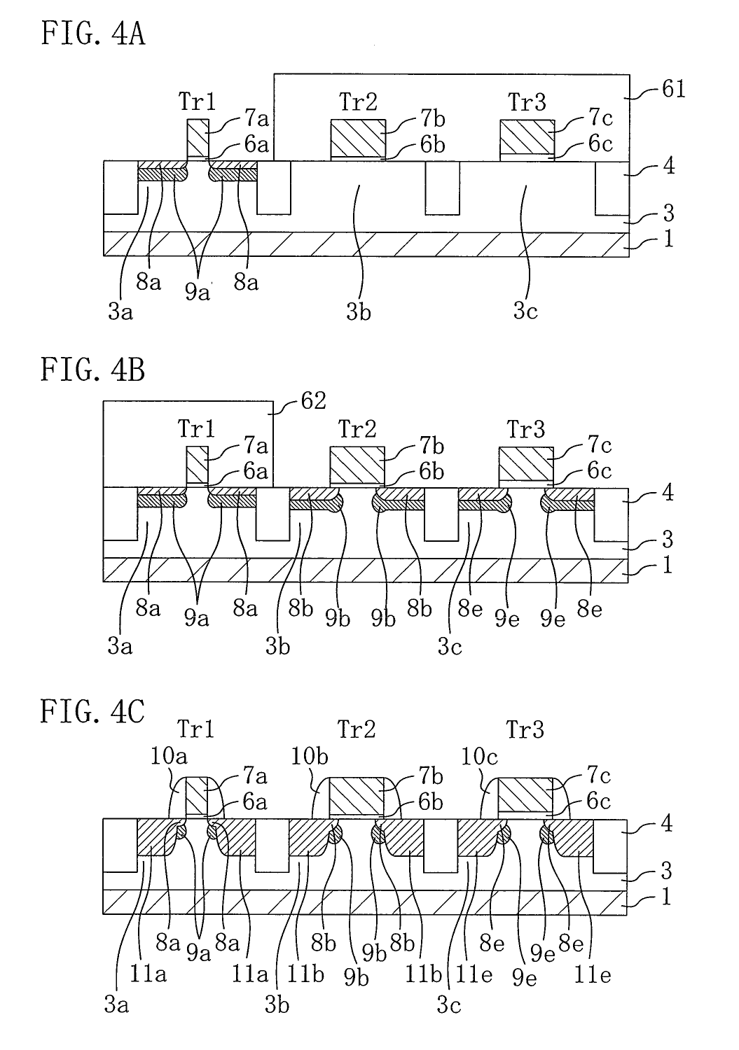

Next, a process flow for manufacturing the semiconductor device of this embodiment will be described with reference FIGS. 4A to 4C. FIGS. 4A to 4C are cross-sectional views showing steps of manufacturing the semiconductor device of the first embodiment. In FIGS. 4A to 4C, the same parts as those of FIG. 3 are indicated by the same reference symbols.

Firstly, in the step of FIG. 4A, a p-type impurity ion is implanted into an upper portion of the P-type semiconductor substrate 1 to form the P-type well 3. Thereafter, the isolation region 4 is formed in the P-type well 3 by shallow trench isolation (STI). Specifically, a trench is formed in a predetermined region of the P-type well 3 by etching, an insulating film is buried in the trench, and the insulating film is flattened by CMP or the like. Thereby, the active regions 3a, 3b, and 3c made of the semiconductor substrate 1 surrounded by the isolation region 4 are formed. Next, a threshold voltage adjusting p-type impurity ion is implanted into portions of the active regions 3a and 3b which will become the channel regions of the 1.2-V transistors Tr1 and Tr2, and a portion of the active region 3c which will become the channel region of the 1.8-V transistor Tr3. Next, the gate insulating film 6c for the transistor Tr3 is formed on the active regions 3a, 3b, and 3c, and thereafter, the gate insulating film 6c on the active regions 3a and 3b is selectively removed, leaving the gate insulating film 6c on the active region 3c. Next, the gate insulating films 6a and 6b for the transistors Tr1 and Tr2 are formed on the active regions 3a and 3b, respectively, by thermal oxidation or the like. By this step, the gate insulating film 6c is caused to be thicker than the gate insulating films 6a and 6b for the transistors Tr1 and Tr2. Next, a polysilicon film is deposited on an entire surface of the semiconductor substrate 1, and thereafter, the polysilicon film is shaped into a gate pattern by dry etching. Thereby, the gate electrodes 7a, 7b, and 7c are formed via the gate insulating films 6a, 6b, and 6c on the active regions 3a, 3b, and 3c, respectively. Next, ion plantation is performed while covering the active regions 3b and 3c with a resist mask 61 so that the extension regions 8a and the pocket regions 9a are formed in regions of the active region 3a located at opposite sides of the gate electrode 7a of the transistor Tr1. The pocket region 9a is formed at a position deeper than the extension region 8a. Specifically, As ions are implanted into the gate electrode 7a at an angle of 0° to form the extension region 8a, where the implantation energy is 2 keV and the dose is 7.0×10¹⁴ cm⁻². Further, In ions are implanted into the gate electrode 7a at an angle of 25° in an amount corresponding to four rotations, where the implantation energy is 55 keV and the dose is 0.5×10¹³ cm⁻². Further, B (boron) ions are implanted into the gate electrode 7a at an angle of 25° in an amount corresponding to four rotations, where the implantation energy is 7 keV and the dose is 1.0×10¹³ cm⁻². Thereby, the pocket region 9a is formed. Note that either the pocket region 9a or the extension region 8a may be formed prior to the other.

Next, in the step of FIG. 4B, after the resist mask 61 is removed, the extension regions 8b and the pocket regions 9b of the transistor Tr2 are formed in the active region 3b, and the extension regions 8e and the pocket regions 9e of the transistor Tr3 are formed in the active region 3c, while covering the active region 3a with a resist mask 62. Here, the extension regions 8b and 8e are simultaneously formed, and the pocket regions 9b and 9e are simultaneously formed. Specifically, As ions are implanted into the gate electrodes 7b and 7c at an angle of 0° to form the extension regions 8b and 8e, respectively, where the implantation energy is 15 keV and the dose is 1.0×10¹⁴ cm⁻². Further, B ions are implanted into the gate electrodes 7b and 7c at an angle of 25° in an amount corresponding to four rotations to form the pocket regions 9b and 9e, respectively, where the implantation energy is 15 keV and the dose is 0.6×10¹³ cm⁻². Here, the impurity concentration of each portion satisfies expression (5) or (6).

Next, in the step of FIG. 4C, after the resist mask 62 is removed, an insulating film is deposited on an entire surface of the semiconductor substrate 1, and thereafter, the sidewalls 10a, 10b, and 10c are self-selectively formed on side surfaces of the gate electrodes 7a, 7b, and 7c, respectively, by dry etching. Next, an n-type impurity ion is implanted into the active regions 3a, 3b, and 3c using the gate electrodes 7a, 7b, and 7c and the sidewalls 10a, 10b, and 10c as a mask, thereby forming the source/drain regions 11a, 11b, and 11e.

In the technique of Japanese Unexamined Patent Application Publication No. 2003-509863, an additional mask is required so as to avoid pocket implantation into an analog transistor. In the manufacturing method of this embodiment, the extension region 8b and the pocket region 9b of the 1.2-V analog transistor Tr2 are simultaneously formed using the same mask that is used for the extension region 8e and the pocket region 9e of the 1.8-V transistor Tr3, respectively. Therefore, according to the method of this embodiment, a variation in characteristics of the analog transistor can be reduced without an increase in manufacturing cost. Also, since the transistor Tr1 whose gate length is short contains a p-type impurity in a higher concentration than that of the transistor Tr2, so that a short-channel effect, such as punch through or the like, can be suppressed.

### Second Embodiment

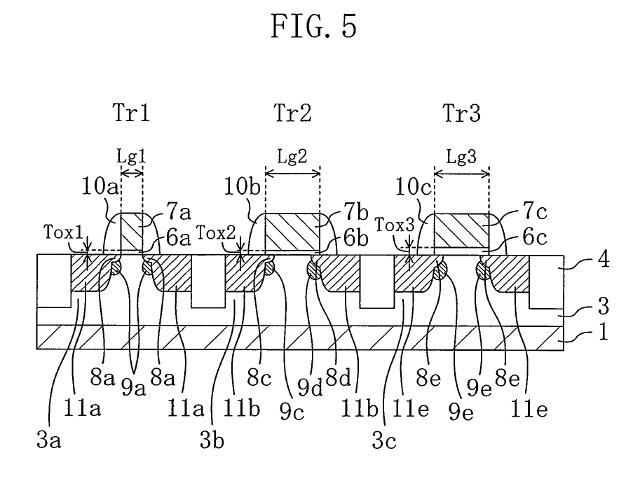

FIG. 5 is a cross-sectional view showing a semiconductor device according to a second embodiment of the present invention. In this embodiment, an N-channel MOS transistor will be described as an example, though the present invention is also applicable to a P-channel MOS transistor. In FIG. 5, Tr1 indicates a 1.2-V core transistor, Tr2 indicates a 1.2-V analog transistor, and Tr3 indicates a 1.8-V transistor. Although Tr3 is assumed to be a 1.8-V transistor in this embodiment, a 2.5- or 3.3-V transistor can also be applicable to the semiconductor device of the present invention. Note that, in FIG. 5, the same parts as those of the semiconductor device of the first embodiment of FIG. 3 are indicated by the same reference symbols. In the semiconductor device of this embodiment, the transistors Tr1 and Tr3 have the same structures as those of the semiconductor device of the first embodiment.

As shown in FIG. 5, the semiconductor device of this embodiment is characterized in that the impurity concentration of a source-side extension region 8d of the 1.2-V analog transistor Tr2 is lower than the impurity concentrations of a drain-side extension region 8c of the 1.2-V analog transistor Tr2 and the extension regions 8a of the 1.2-V core transistor Tr1, and the impurity concentration of a source-side pocket region 9d of the 1.2-V analog transistor Tr2 is lower than the impurity concentrations of a drain-side pocket region 9c of the 1.2-V analog transistor Tr2 and the pocket regions 9a of the 1.2-V core transistor Tr1. The impurity concentrations of the source-side pocket region 9d and the source-side extension region 8d are also the same as the impurity concentrations of the pocket regions 9e and the extension regions 8e of the 1.8-V transistor Tr3, respectively. The impurity concentrations of the drain-side pocket region 9c and the drain-side extension region 8c are the same as the impurity concentrations of the pocket regions 9a and the extension regions 8a of the 1.2-V core transistor Tr1, respectively.

Source-side pocket implantation has a larger influence on a random variation in electrical characteristics than that of drain-side pocket implantation. In the semiconductor device of this embodiment, the impurity concentration of the source-side pocket region 9d of the 1.2-V analog transistor Tr2 is set to be lower than the impurity concentrations of the drain-side pocket region 9c and the pocket regions 9a of the 1.2-V core transistor Tr1, thereby making it possible to effectively suppressing a random variation in electrical characteristics. On the other hand, the impurity concentration of the drain-side extension region 8c of the 1.2-V analog transistor Tr2 is set to be the same as the impurity concentration of the extension regions 8a of the 1.2-V core transistor Tr1, thereby making it possible to suppress a short-channel effect of the 1.2-V analog transistor Tr2 as compared to the semiconductor device of the first embodiment. Note that only transistors whose sources and drains each have a fixed direction are applicable to the semiconductor device of this embodiment.

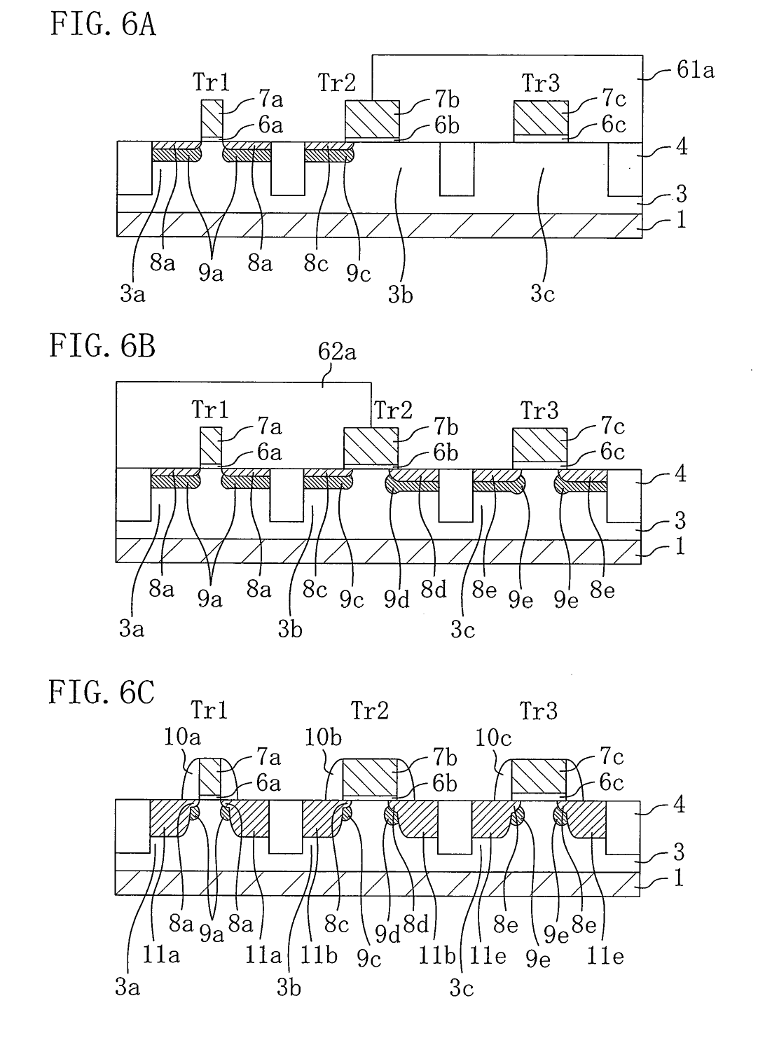

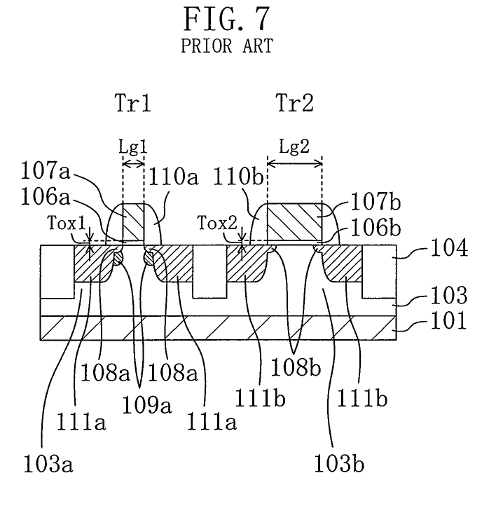

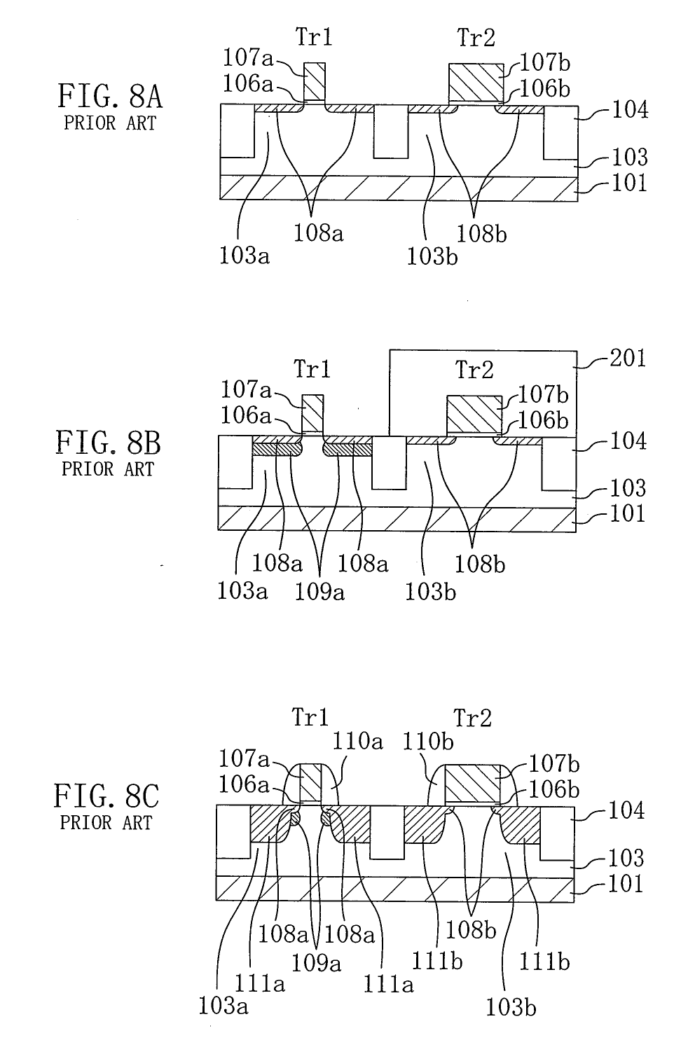

Next, a flow of a process for manufacturing the semiconductor device of this embodiment will be described with reference to FIGS. 6A to 6C. FIGS. 6A to 6C are cross-sectional views showing steps of manufacturing the semiconductor device of the second embodiment.

Firstly, in the step of FIG. 6A, as in the first embodiment, the P-type well 3, the active regions 3a, 3b, and 3c, the isolation region 4, the gate insulating films 6a, 6b, and 6c, and the gate electrodes 7a, 7b, and 7c are formed. Next, ion implantation is performed while covering the source-side region of the active region 3b and the active region 3c with a resist mask 61a, thereby forming the extension regions 8a and the pocket regions 9a in regions of the active region 3a located at opposite sides of the gate electrode 7a, and the drain-side extension region 8c and the pocket region 9c in a region of the active region 3b located at one side (drain side) of the gate electrode 7b. Specifically, As ions are implanted into the gate electrodes 7a and 7b at an angle of 0° to form the extension regions 8a, where the implantation energy is 2 keV and the dose is 7.0×10¹⁴ cm⁻². Also, In ions are implanted into the gate electrodes 7a and 7b at an angle of 25° in an amount corresponding to four rotations, where the implantation energy is 55 keV and the dose is 0.5×10¹³ cm⁻². Further, B ions are implanted into the gate electrodes 7a and 7b at an angle of 25° in an amount corresponding to four rotations, where the implantation energy 7 keV and the dose 1.0×10¹³ cm⁻². Thereby, the pocket regions 9a and the drain-side pocket region 9c are formed. In this step, the resist mask 61a is provided, covering from a region where the gate electrode 7c is provided to a region on a portion of the gate electrode 7b. Note that either the pocket region 9a or the extension region 8a may be formed prior to the other.

Next, in the step of FIG. 6B, after the resist mask 61a is removed, ion implantation is performed while covering the drain-side regions of the active region 3a and the active region 3b with a resist mask 62a, thereby forming the source-side extension region 8d and the source-side pocket region 9d in a region of the active region 3b located at the other side (source side) of the gate electrode 7b, and the extension regions 8e and the pocket regions 9e in regions of the active region 3c located at opposite sides of the gate electrode 7c. Specifically, As ions are implanted into the gate electrodes 7b and 7c at an angle of 0° to form the extension regions 8d and 8e, where the implantation energy is 15 keV and the dose is 1.0×10¹⁴ cm⁻². Further, B ions are implanted into the gate electrodes 7b and 7c at an angle of 25° in an amount corresponding to four rotations to form the pocket regions 9d and 9e, where the implantation energy is 15 keV and the dose is 0.6×10¹³ cm⁻². In this step, the resist mask 62a is provided, covering from a region where the gate electrode 7a is provided to a region on a portion of the gate electrode 7b. Note that the channel length of the 1.2-V analog transistor Tr2 needs to be more than two times as large as a specified positional deviation between the resist mask 61a or the resist mask 62a and the mask for forming gate electrodes 7a, 7b, and 7c of the transistor, which are superposed. In the 45-nm generation process, the specified positional deviation is about 30 nm and the minimum value of Lg2 is 0.10 μm, which values satisfy the above-described conditions. Therefore, the semiconductor device of this embodiment can be easily manufactured using the 45-nm generation process. The manufacturing method of this embodiment is similarly applicable to the 130- to 45-nm generation processes.

Next, in the step of FIG. 6(c), after the resist mask 62a is removed, an insulating film is deposited on an entire surface of the semiconductor substrate 1, followed by dry etching to self-selectively form the sidewalls 10a, 10b, and 10c on side surfaces of the gate electrodes 7a, 7b, and 7c, respectively. Next, the source/drain regions 11a, 11b, and 11e are formed by implanting an n-type impurity into the active regions 3a, 3b, and 3c while using the gate electrodes 7a, 7b, and 7c and the sidewalls 10a, 10b, and 10c as a mask, respectively. The semiconductor device of this embodiment can be thus manufactured.

The above-described semiconductor device and manufacturing method of the present invention are applicable to a semiconductor device comprising both a core transistor and an analog transistor.

What is claimed is:

1. A semiconductor device comprising:
a first transistor including:
a first active region surrounded by an isolation region formed in a semiconductor substrate;
a first gate insulating film formed on the first active region;
a first gate electrode formed on the first gate insulating film; and
first pocket regions of a first conductivity type formed at opposite sides of the first gate electrode in the first active region, and
a second transistor including:
a second active region surrounded by an isolation region formed in the semiconductor substrate;
a second gate insulating film formed on the second active region;
a second gate electrode formed on the second gate insulating film; and
second pocket regions of the first conductivity type formed at opposite sides of the second gate electrode in the second active region,
wherein a concentration of an impurity of the first conductivity type in the second pocket regions is lower than a concentration of an impurity of the first conductivity type in the first pocket regions.

2. The semiconductor device of claim 1, wherein
the first transistor further includes:
a first sidewall formed on a side surface of the first gate electrode; and
first source/drain regions of a second conductivity type formed outside the first sidewall in the first active region, and
the second transistor further includes:
a second sidewall formed on a side surface of the second gate electrode; and
second source/drain regions of the second conductivity type formed outside the second sidewall in the second active region.

3. The semiconductor device of claim 1, wherein
the first transistor further includes:
first extension regions of a second conductivity type formed at the opposite sides of the first gate electrode and on the first pocket regions in the first active region,
the second transistor further includes:
second extension regions of the second conductivity type formed at the opposite sides of the second gate electrode and on the second pocket regions in the second active region.

4. The semiconductor device of claim 1, wherein
concentrations of the first conductivity type impurity of the second pocket regions formed at the opposite sides of the second gate electrode in the second active region are both lower than that concentrations of the first conductivity type impurity of the first pocket regions.

5. The semiconductor device of claim 1, wherein
a concentration of the first conductivity type impurity of the second pocket region formed at one of the opposite sides of the second gate electrode in the second active region is lower than a concentration of the first conductivity type impurity of the second pocket region formed at the other of the opposite sides of the second gate electrode in the second active region.

6. The semiconductor device of claim 5, wherein
the concentration of the first conductivity type impurity of the second pocket region formed at the other of the opposite sides of the second gate electrode in the second active region is equal to the concentration of the first conductivity type impurity of the first pocket regions.

7. The semiconductor device of claim 1, wherein
the second transistor has a gate length larger than that of the first transistor.

8. The semiconductor device of claim 1, wherein
the first transistor and the second transistor are driven by equal power supply voltages.

9. The semiconductor device of claim 1, wherein
the first gate insulating film has the same film thickness as that of the second gate insulating film.

10. The semiconductor device of claim 1, further comprising:
a third transistor including:
a third active region surrounded by an isolation region formed in a semiconductor substrate;
a third gate insulating film formed on the third active region;
a third gate electrode formed on the third gate insulating film; and
third pocket regions of the first conductivity type formed at opposite sides of the third gate electrode in the third active region,
wherein the third gate insulating film has a film thickness larger than those of the first gate insulating film and the second gate insulating film, and
a concentration of an impurity of the first conductivity type of the third pocket regions is lower than the concentration of the first conductivity type impurity of the first pocket regions, and is equal to a concentration of the first conductivity type impurity of at least one of the second pocket regions formed at the opposite sides of the second gate electrode in the second active region.

11. The semiconductor device of claim 10, wherein
the third transistor further includes:
a third sidewall formed on a side surface of the third gate electrode; and
third source/drain regions of a second conductivity type formed outside the third sidewall in the third active region.

12. A method for manufacturing a semiconductor device including a first transistor having a first gate insulating film on a first active region formed in a semiconductor substrate, a first gate electrode, and first pocket regions, a second transistor having a second gate insulating film on a second active region formed in the semiconductor substrate, a second gate electrode, and second pocket regions, and a third transistor having a third gate insulating film on a third active region formed in the semiconductor substrate, a third gate electrode, and third pocket regions, the method comprising the steps of:
(a) forming the first active region, the second active region, and the third active region in the semiconductor substrate, each of the first active region, the second active region, and the third active region being surrounded by an isolation region;
(b) forming the first gate insulating film and the first gate electrode on the first active region, the second gate insulating film and the second gate electrode on the second active region, and the third gate insulating film and the third gate electrode on the third active region;
(c) forming the first pocket regions of a first conductivity type at opposite sides of the first gate electrode in the first active region; and
(d) forming the second pocket region of the first conductivity type at least one of the opposite sides of the second gate electrode in the second active region, and the third pocket regions of the first conductivity type at opposite sides of the third gate electrode in the third active region,
wherein the third gate insulating film has a film thickness larger than those of the first gate insulating film and the second gate insulating film, and
a concentration of the first conductivity type impurity of the third pocket regions is lower than a concentration of the first conductivity type impurity of the first pocket regions, and is equal to a concentration of the first conductivity type impurity of the second pocket region formed at the at least one of the opposite sides of the second gate electrode in the second active region.

13. The method of claim 12, wherein
the step (c) includes forming first extension regions of a second conductivity type at opposite sides of the first gate electrode in the first active region,
the step (d) includes forming second extension regions of the second conductivity type at the opposite sides of the second gate electrode in the second active region, and
the first extension regions are formed in regions located on the first pocket regions, and the second extension regions are formed in regions located on the second pocket regions.

14. The method of claim 12, further comprising:
(e) after the steps (c) and (d), forming a first sidewall on a side surface of the first gate electrode, a second sidewall on a side surface of the second gate electrode, and a third sidewall on a side surface of the third gate electrode; and
(f) forming first source/drain regions of a second conductivity type outside the first sidewall in the first active region, second source/drain regions of the second conductivity type outside the second sidewall in the second active region, and third source/drain regions of the second conductivity type outside the third sidewall in the third active region.

15. The method of claim 12, wherein
in the step (d), the second pocket regions are formed at the opposite sides of the second gate electrode in the second active region at the same time when the third pocket regions are formed.

16. The method of claim 12, wherein
in the step (c), the second pocket region of the first conductivity type is formed at the other of the opposite sides of the second gate electrode in the second active region at the same time when the first pocket regions are formed, and
in the step (d), the second pocket region of the first conductivity type is formed at one of the opposite sides of the second gate electrode in the second active region at the same time when the third pocket regions are formed.

17. The method of claim 12, wherein
the first transistor and the second transistor are driven by equal power supply voltages, and the third transistor is driven by a power supply voltage higher than those of the first transistor and the second transistor.

18. The method of claim 12, wherein
a gate length, denoted a, of the first transistor, a gate length, denoted b, of the second transistor, and a gate length, denoted c, of the third transistor satisfy a<b<c.
